(19) United States
(12) Patent Application Publication
(10) Pub. No.: US 2026/0343930 A1
(43) Pub. Date: Oct. 29, 2026

(54) ENHANCEMENT-MODE GaN HIGH ELECTRON MOBILITY TRANSISTOR

(71) Applicant: SK keyfoundry Inc., Cheongju-si (KR)

(72) Inventors: Seongyong JANG, Cheongju-si (KR); Hyunchul KIM, Cheongju-si (KR); Soochang KANG, Cheongju-si (KR); Yohan LEE, Cheongju-si (KR); Yonsup PANG, Cheongju-si (KR)

(73) Assignee: SK keyfoundry Inc., Cheongju-si (KR)

(21) Appl. No.: 19/533,458

(22) Filed: Feb. 9, 2026

(30) Foreign Application Priority Data
Apr. 14, 2025 (KR) 10-2025-0048253

(51) Int. Cl. H10D 30/47; H10D 30/01; H10D 62/10; H10D 62/824; H10D 64/00

(52) U.S. Cl. CPC H10D 30/475; H10D 30/015; H10D 62/102; H10D 62/824; H10D 64/112; H10D 64/117

(57) ABSTRACT

A gallium nitride high electron mobility transistor (GaN HEMT) includes a silicon substrate, an undoped aluminum gallium nitride buffer, and an n-type GaN channel. An aluminum nitride spacer is formed on the n-type GaN channel, and a two-dimensional electron gas is formed at a heterointerface between the n-type GaN channel and the aluminum nitride spacer. An n-type aluminum gallium nitride barrier is formed on the aluminum nitride spacer, and an undoped GaN layer is formed on the n-type aluminum gallium nitride barrier. A p-type gallium nitride gate is formed over the aluminum gallium nitride barrier and laterally adjacent to the undoped GaN layer, with a gate metal formed thereon. Source and drain metals provide ohmic contact to the n-type GaN channel. The GaN HEMT operates in enhancement mode and is normally off at a gate-to-source voltage of zero volts.

### CROSS REFERENCE TO RELATED APPLICATION

The present application claims the benefit under 35 U.S.C. §119(a) of Korea Patent Application No. 10-2025-0048253, filed on Apr. 14, 2025, the entire disclosure of which is incorporated herein by reference for all purposes.

### BACKGROUND

### 1. Field

The following description relates to an Enhancement-mode (E-mode) GaN high electron mobility transistor (HEMT).

### 2. Discussion of Related Art

The statements in this section merely provide background information related to the present disclosure and do not necessarily constitute prior art.

Gallium Nitride (GaN) high electron mobility transistors (HEMTs) provide lower on-state resistance (R_{DS(on)}), higher breakdown voltage, and faster switching speeds when compared with conventional silicon based metal oxide semiconductor field effect transistors (MOSFETs). The reduced on-state resistance results in lower conduction losses and reduced heat generation during operation. The higher breakdown voltage enables operation at elevated voltages while maintaining a smaller device footprint. Additionally, the faster switching capability allows the use of smaller passive components, such as inductors and capacitors, thereby enabling reduced size and increased power density in power converters and power supply modules.

The performance of a GaN HEMT is largely determined by the heterojunction interface between an aluminum gallium nitride (AlGaN) layer and a GaN layer. Due to differences in crystal lattice structure and internal strain between these two layers, a high density electron channel forms at the interface. This channel, commonly referred to as a two-dimensional electron gas (2DEG), constitutes a thin, highly conductive sheet of electrons exhibiting very high carrier mobility. Because the electrons in the 2DEG are spatially separated from ionized dopant atoms, they enable low channel resistance and high-speed switching.

Although the 2DEG provides excellent theoretical performance, in practical devices, it is sensitive to the physical and electrical environment of the transistor. One known reliability issue associated with GaN HEMTs is current collapse, a phenomenon in which the on-state resistance (R_{DS(on)}) increases significantly following exposure to high-voltage or high-electric field stress. Current collapse limits the maximum power the transistor can handle and can lead to overheating.

During high-voltage operation, some electrons originating from the gate region or the channel may acquire sufficient energy to escape the conduction channel and become trapped at surface states of the AlGaN layer or within defect states in the buffer layer. The accumulation of these trapped electrons creates a localized region of negative charge between the gate and the drain. This negatively charged region acts as a parasitic or “virtual gate” that locally depletes the underlying 2DEG. As a result, even when the gate is biased to an on-state, the virtual gate stays “off,” restricting current flow and collapsing the performance.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

The present disclosure aims to provide an enhancement-mode GaN HEMT that minimizes traps generated during the fabrication process, thereby improving reliability and preventing performance degradation such as current collapse.

The technical problem to be addressed by the present disclosure is not limited to the above-mentioned technical problem, and other technical problems not explicitly described herein will be readily understood by those of ordinary skill in the art to which the present disclosure pertains from the following description.

According to an embodiment of the present disclosure, it is possible to provide the GaN HEMT having high reliability and capable of maintaining a constant performance by adding a region constantly doped or a layer consisting of a certain material to a structure of the GaN HEMT.

In one general aspect, a gallium nitride high electron mobility transistor (GaN HEMT) includes: a silicon substrate; an undoped aluminum gallium nitride buffer (undoped AlGaN buffer) formed on the silicon substrate; an n-type GaN channel (n-GaN channel) formed on the undoped AlGaN buffer; a two-dimensional electron gas (2DEG) at a heterointerface between the n-GaN channel and an aluminum nitride spacer (AlN spacer); the AlN spacer formed on the n-GaN channel; an n-type AlGaN barrier (n-AlGaN barrier) formed on the AlN spacer; an undoped GaN layer formed on the n-AlGaN barrier; a p-type gallium nitride gate (p-GaN gate) formed over the n-AlGaN barrier and laterally adjacent to the undoped GaN layer; a gate metal formed on the p-GaN gate; and a source metal and a drain metal formed on the n-GaN channel, the source metal and the drain metal providing ohmic contact to the n-GaN channel. The n-AlGaN barrier is formed between the AlN spacer and the undoped GaN layer, and the transistor is an enhancement-mode device configured to be normally off at VGS=0 V.

The n-AlGaN barrier may have a thickness greater than a thickness of the AlN spacer, and the AlN spacer may have a thickness from 0.5 nm to 1.0 nm.

The undoped GaN layer may include a first undoped GaN layer disposed between the p-GaN gate and the source metal and a second undoped GaN layer disposed between the p-GaN gate and the drain metal.

The GaN HEMT may further include: an oxide passivation layer formed on the undoped GaN layer; a nitride passivation layer formed on the oxide passivation layer; and an inter-layer dielectric layer formed on the nitride passivation layer. The oxide passivation layer may be in direct contact with the p-GaN gate, the undoped GaN layer, and the gate metal. The oxide passivation layer may include SiO₂ or Al₂O₃ and the nitride passivation layer may include SiN, SiON, AlN, or BN. The oxide passivation layer and the nitride passivation layer may be configured to reduce interface state density and mitigate current collapse.

The GaN HEMT may further include a first field plate formed on the nitride passivation layer and laterally adjacent to the gate metal, a second field plate formed over the first field plate, overlapping a portion of the gate metal and extending toward the drain metal, and a third field plate overlapping formed to overlap a portion of the drain metal. The field plates may be configured to reduce peak electric field and enhance breakdown voltage.

The undoped GaN layer may be formed in direct contact with the n-AlGaN barrier, the p-GaN gate, and the oxide passivation layer. The p-GaN gate may be formed in direct contact with the undoped GaN layer, the gate metal, and the oxide passivation layer. The gate metal may be formed in direct contact with the p-GaN gate, the oxide passivation layer, the nitride passivation layer, and the inter-layer dielectric layer.

In another general aspect, a gallium nitride high electron mobility transistor (GaN HEMT) includes: a silicon substrate, an undoped AlGaN buffer and an n-GaN channel formed sequentially; an AlN spacer formed on the n-GaN channel; a p-AlGaN barrier and an undoped AlGaN barrier formed on the AlN spacer; a p-GaN gate and an undoped GaN layer formed on the p-AlGaN barrier and the undoped AlGaN barrier, respectively; a gate metal formed on the p-GaN gate; and a source metal and a drain metal formed of a same metal stack as the gate metal, spaced apart from the gate metal, and formed in direct contact with the n-GaN channel. The transistor may be an enhancement-mode device configured to be normally off at VGS=0 V.

The p-AlGaN barrier and the undoped AlGaN barrier may be formed in parallel to each other and share a bottom surface with each other.

The undoped AlGaN barrier may contact the p-AlGaN barrier on a side surface, contact the AlN spacer on a bottom surface, and contact the undoped GaN layer on an upper surface.

The GaN HEMT may further include: an oxide passivation layer formed on the undoped GaN layer; a nitride passivation layer formed on the oxide passivation layer; and an inter-layer dielectric layer formed on the nitride passivation layer. The oxide passivation layer may be in direct contact with the p-GaN gate, the undoped GaN layer, and the gate metal. The oxide passivation layer and the nitride passivation layer may be configured to neutralize surface states between the gate metal and the drain metal and suppress a virtual-gate effect during high-speed switching.

The undoped GaN layer may be in direct contact with the p-GaN gate and the oxide passivation layer, and the p-GaN gate may be in direct contact with the undoped GaN layer, the oxide passivation layer, the p-AlGaN barrier, and the gate metal. The gate metal may be in direct contact with the p-GaN gate, the oxide passivation layer, the nitride passivation layer, and the inter-layer dielectric layer.

In another general aspect, a method of manufacturing an enhancement-mode gallium nitride high electron mobility transistor (GaN HEMT) includes: forming an AlN thin film layer on a silicon substrate; forming an undoped AlGaN buffer on the AlN thin film layer; forming an n-GaN channel on the undoped AlGaN buffer; forming an AlN spacer on the n-GaN channel; forming an AlGaN barrier on the AlN spacer; forming a p-GaN gate on the AlGaN barrier; annealing the semiconductor structure formed by the AlGaN barrier and the p-GaN gate to diffuse magnesium from the p-GaN gate into the AlGaN barrier to convert, beneath the p-GaN gate, a portion of the AlGaN barrier to a p-AlGaN barrier; forming an undoped GaN layer on the AlGaN barrier laterally adjacent the p-GaN gate; forming an oxide passivation layer on the undoped GaN layer and a nitride passivation layer on the oxide passivation layer; and forming source, drain, and gate metals, the source and drain metals contacting the n-GaN channel. The device may be normally off at VGS=0 V, and the undoped GaN layer and a passivation stack formed by the oxide passivation layer and the nitride passivation layer may be configured to reduce trap formation and mitigate current collapse.

The AlN spacer may have a thickness from 0.5 nm to 1.0 nm and the AlGaN barrier may have a thickness greater than the thickness of the AlN spacer.

The undoped GaN layer may include first and second undoped GaN regions disposed on opposite sides of the p-GaN gate, respectively adjacent the source metal and the drain metal.

The oxide passivation layer may include silicon oxide or aluminum oxide and the nitride passivation layer may include silicon nitride, silicon oxynitride, aluminum nitride, or boron nitride, to reduce interface state density and suppress a virtual-gate effect between the gate metal and the drain metal.

The method may further include forming at least one field plate over the nitride passivation layer to reduce peak electric fields near the gate metal or the drain metal. The gate metal, the source metal, and the drain metal may include a common metal stack selected from Ti/Al/Ni/Au, Ti/Al/TiN, and Ti/Al/W.

Other features and aspects will be apparent from the following detailed description, the drawings, and the claims.

Effects which may be obtained by the present disclosure are not limited to the aforementioned effects, and other technical effects not described above may be evidently understood by a person having ordinary skill in the art to which the present disclosure pertains from the following description.

### BRIEF DESCRIPTION OF THE DRAWINGS

FIG. 1 is a cross-sectional view illustrating a structure of a first gallium nitride high electron mobility transistor (GaN HEMT) according to a first embodiment of the present disclosure.

FIG. 2 is an enlarged cross-sectional view of a portion of the first GaN HEMT illustrated in FIG. 1.

FIG. 3 is an enlarged cross-sectional view of a portion of the first GaN HEMT illustrated in FIG. 2.

FIG. 4 is a cross-sectional view illustrating a structure of a second GaN HEMT according to a second embodiment of the present disclosure.

FIG. 5 is an enlarged cross-sectional view of a portion of the second GaN HEMT illustrated in FIG. 4.

FIG. 6 is an enlarged cross-sectional view of a portion of the second GaN HEMT illustrated in FIG. 5.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art. Furthermore, the present disclosure is only defined by scopes of claims. Like reference numerals refer to like elements throughout.

The use of the term “may” herein with respect to an example or embodiment, e.g., as to what an example or embodiment may include or implement, means that at least one example or embodiment exists where such a feature is included or implemented, while all examples are not limited thereto.

When an arbitrary component is described as “being connected to “or” being linked to” another component, this should be understood to mean that still another component(s) may exist between them, although the arbitrary component may be directly connected to, or linked to, the second component. In contrast, when an arbitrary component is described as “being directly connected to” or “being directly linked to” another component, this should be understood to mean that no component exists between them. “And/or” comprises all of one or more combinations defined by related components.

The terms used in the present application are used to describe only specific embodiments or examples, and are not intended to limit the present disclosure. A singular expression can comprise a plural expression as long as it does not have an apparently different meaning in context. In a case where ‘comprise’, ‘have’, and ‘comprise’ described in the present specification are used, another part may be added unless ‘only\tilde{ }’ is used. The terms of a singular form may comprise plural forms unless referred to the contrary.

Although the terms including an ordinal number such as first, second, etc. may be used for describing various elements, the structural elements are not restricted by the terms. The terms are only used to distinguish one element from another element.

Therefore, a first component to be mentioned below may be a second component in a technical concept of the present disclosure. Unless otherwise defined, all terms including technical and scientific terms used herein have the same meaning as commonly understood by one of ordinary skill in the art to which this disclosure belongs. It will be further understood that terms, such as those defined in commonly used dictionaries, will not be interpreted in an idealized or overly formal sense unless expressly so defined herein.

A term “part” or “module” used in the embodiments may mean software components or hardware components such as a field programmable gate array (FPGA), an application specific integrated circuit (ASIC). The “part” or “module” performs certain functions. However, the “part” or “module” is not meant to be limited to software or hardware. The “part” or “module” may be configured to be placed in an addressable storage medium or to restore one or more processors. Thus, for one example, the “part” or “module” may comprise components such as software components, object-oriented software components, class components, and task components, and may comprise processes, functions, attributes, procedures, subroutines, segments of a program code, drivers, firmware, microcode, circuits, data, databases, data structures, tables, arrays, and variables. Components and functions provided in the “part” or “module” may be combined with a smaller number of components and “parts” or “modules” or may be further divided into additional components and “parts” or “modules”.

Methods or algorithm steps described relative to some embodiments of the present disclosure may be directly implemented by hardware and software modules that are executed by a processor or may be directly implemented by a combination thereof. The software module may be resident on a RAM, a flash memory, a ROM, an EPROM, an EEPROM, a resistor, a hard disk, a removable disk, a CD-ROM, or any other type of record medium known to those skilled in the art. An exemplary record medium is coupled to a processor and the processor can read information from the record medium and can record the information in a storage medium. In another way, the record medium may be integrally formed with the processor. The processor and the storage medium may reside in an application specific integrated circuit (ASIC). The ASIC may be resident within a user's terminal.

Hereinafter, a detailed description will be given as to the embodiments of the present disclosure with reference to the accompanying drawings in order for those skilled in the art to embody the present disclosure with ease. But the present disclosure is susceptible to variations and modifications and not limited to the embodiments described herein.

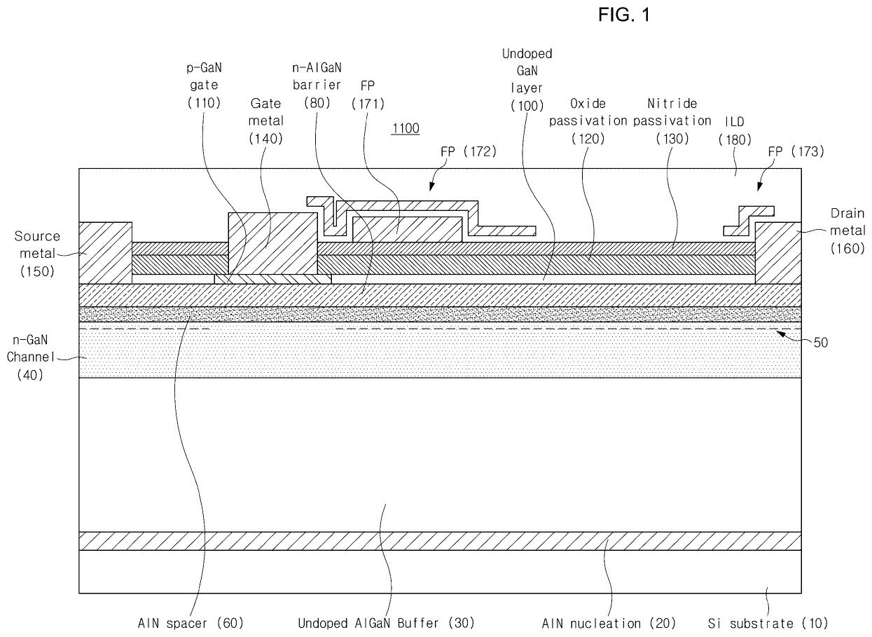

FIG. 1 is a cross-sectional view illustrating a structure of a gallium nitride high electron mobility transistor (GaN HEMT) according to a first embodiment of the present disclosure.

Referring to FIG. 1, the enhancement-mode GaN HEMT 1100 according to an example embodiment of the present disclosure may form a smaller drift region of a device while having the same off-state breakdown voltage (BVDSS) between the drain and the source compared to that of a general silicon-based HEMT. Here, the drift region refers to a region between a gate metal 140 and a drain metal 160. Therefore, the enhancement-mode GaN HEMT 1100 has a high critical electric field, and has a high electric stability.

In addition, a 2DEG 50 region of the enhancement-mode GaN HEMT 1100 has a high electron mobility, and thus, the enhancement-mode GaN HEMT 1100 has advantages in that an on-resistance (Specific on-resistance: Rsp=Ron*WG(gate width)*Lpitch(pitch size)) is low and a drain saturation current is high.

The enhancement-mode GaN HEMT 1100 has a low intrinsic carrier concentration and thus, may generate a less leakage current. In case of a general HEMT, in order to increase the off-state drain-to-source breakdown voltage (BVDSS), a length of the drift region must be extended and a doping concentration must be lowered. In addition, in order to decrease the Rsp, the length of the drift region must be decreased and the doping concentration must be increased. Therefore, there is a trade-off relationship between the BVDSS and the Rsp, however, the enhancement-mode GaN HEMT 1100 may reduce such a trade-off relationship through the above-described advantages.

Referring to FIG. 1, the enhancement-mode GaN HEMT 1100 according to the embodiment of the present disclosure may be formed on a silicon substrate 10 in a crystal orientation {1 1 1}. According to the embodiment of the present disclosure, boron B may be doped in the silicon substrate 10 of the enhancement-mode GaN HEMT 1100, and at this instance, the boron may be doped at a concentration of 1E18 to 5E19/cm³.

The enhancement-mode GaN HEMT 1100 may be formed on a substrate formed of sapphire, silicon carbide SiC, and the like, instead of silicon substrate 10. These materials cost high expenses in manufacture and have a process difficulty compared to silicon, however, have an advantage of having high heat conductivity and in case of SiC in particular, SiC has an advantage in that SiC has less lattice defects with other materials compared to silicon.

On the {1 1 1} silicon substrate 10 of the enhancement-mode GaN HEMT 1100, an aluminum nitride (AlN) thin film layer 20 of 100 to 240 nm may be formed. The substrate may be formed by using silicon, sapphire Al2O3, or silicon carbide, and the silicon substrate costs less, heat conductivity thereof is permissible, and may be processed through a standard silicon foundry process. However, the silicon substrate 10 has characteristics in that lattice mismatch is great and thermal expansion coefficient (CTE) mismatch is very great.

The silicon substrate 10 and an undoped AlGaN buffer 30, each has a different lattice constant with each other. Therefore, when depositing the undoped AlGaN buffer 30 directly on the silicon substrate 10, many dislocations may be generated. Therefore, in order to reduce detect generation, before depositing the undoped AlGaN buffer 30, an AlN thin film layer 20 may be formed in advance thereon. Here, the AlN thin film layer 20 may be formed to have a thickness of 100 to 240 nm.

By forming the AlN thin film layer 20, it is possible to reduce a thermo-elastic strain due to the high heat which may be generated between different materials of the HEMT and the silicon substrate 10. Therefore, it becomes possible to improve the performance of the enhancement-mode GaN HEMT 1100 by reducing cracking or dislocations on the undoped AlGaN buffer 30. In addition, the AlN thin film layer 20 may improve a current processing ability and a switching speed by enhancing an electron mobility through improvement of a quality of a boundary surface of materials of the enhancement-mode GaN HEMT 1100.

In the first embodiment of the present disclosure, the undoped AlGaN buffer 30 may be formed on the AlN thin film layer 20. Since the undoped AlGaN buffer 30 has a super-lattice structure, a substrate-leakage may be reduced by increasing a thickness of the undoped AlGaN buffer 30.

According to the first embodiment, as a doping concentration of aluminum may increase in the undoped AlGaN buffer 30, it is possible to effectively ease the lattice constant difference. AlGaN, AlN or GaN may replace the undoped AlGaN buffer 30. Alternatively, a carbon-doped AlGaN super-lattice (SL) buffer structure may replace the undoped AlGaN buffer 30. When using the carbon-doped AlGaN super-lattice (SL) buffer structure, it is possible to improve an electric field and a breakdown voltage in a vertical direction and a breakdown voltage in a horizontal direction of the enhancement-mode GaN HEMT. In addition, by reducing a quantity of traps, the carbon-doped AlGaN super-lattice (SL) buffer structure may reduce the on-resistance and may increase a life expectancy of the enhancement-mode GaN HEMT 1100.

According to the first embodiment, an n-type gallium nitride (n-GaN) channel 40 may be formed on the undoped AlGaN buffer 30. A thickness and doping concentration of the n-GaN channel 40 may affect an electric characteristic of the enhancement-mode GaN HEMT 1100. The n-GaN channel 40 is a silicon-doped n-GaN channel, and as a concentration of the silicon doping increases, the conductivity increases as well, thereby increasing the drain saturation current. The n-GaN channel 40 may contain silicon Si, which is an n-type dopant, by as much as 1E17/cm3 to 1E18/cm3. As the n-type silicon (Si) dopant is doped on the n-GaN channel 40, a conductivity of the n-GaN channel may be increased, thereby a drain saturation current may be increased. A thickness of the n-GaN channel 40 may be 200 to 2000 nm.

According to the first embodiment, a thin aluminum nitride (AlN) spacer 60 may be formed on the n-GaN channel 40. The AlN spacer 60 may improve enhancement-mode GaN HEMT 1100 performance by better confinement of electrons in the 2DEG 50 region. The thin AlN spacer 60 may be formed to be very thin with a thickness of 0.5 to 1.0 nm. Here, the AlN spacer 60 may be formed in direct contact with the n-GaN channel 40 and an n-type Aluminum Gallium Nitride (n-AlGaN) barrier 80. When the thin AlN spacer 60 is formed on the n-GaN channel 40, a 2DEG 50 layer, which is a very thin conductive layer, is formed on a boundary surface between the n-GaN channel 40 and the AlN spacer 60 due to a different band gap energy between the AlN spacer 60 of which the band gap is about 6.2 eV and the n-GaN channel 40 of which the band gap is about 3.4 eV, and thus, it becomes possible to move a charge with an excellent performance in a situation of a high current and a high voltage.

The AlN spacer 60 is more effective in strengthening the 2DEG 50 region. The AlN spacer 60 is a polar substance having a very great band gap of about 6.2 eV, and as the thin AlN spacer 60 is formed between the n-GaN channel 40 and the n-AlGaN barrier 80, it is possible to form a strong electric field due to the polarity and a higher potential barrier on the boundary surface between the n-GaN channel 40 and the AlN spacer 60. Therefore, it is possible to improve a current delivery ability by forming a higher electron density in the 2DEG 50 region formed in the n-GaN channel 40.

However, when applying a lower gate voltage to the enhancement-mode GaN HEMT 1100 in an off-state, an electron density required to turn on the enhancement-mode GaN HEMT 1100 may be easily reached in the 2DEG 50 region positioned below a p-type gallium nitride (p-GaN) gate 110. Therefore, when adding the structure of the AlN spacer 60, the drain current of the enhancement-mode GaN HEMT 1100 can be easily increased and therefore, the threshold voltage can be lowered.

Referring to FIG. 1, the enhancement-mode GaN HEMT 1100 according to the embodiment may comprise the n-AlGaN barrier 80 formed on the thin AlN spacer 60. The n-AlGaN barrier 80 may serve to lower the threshold voltage. However, the n-AlGaN barrier 80 may contribute to improvement of the performance of the enhancement-mode GaN HEMT 1100. In order to satisfy design specifications of the enhancement-mode GaN HEMT 1100 with respect to the threshold voltage, the saturation drain current, and the on-resistance of the enhancement-mode GaN HEMT, optimization of other design variables of the enhancement-mode GaN HEMT 1100 as well as adjustment of the doping concentration of the n-AlGaN barrier 80 may be needed.

According to the first embodiment, the undoped GaN layer 100 may be formed on the n-AlGaN barrier 80. The undoped GaN layer 100 may be formed with a thickness of 80 to 100 nm. By using the undoped GaN layer 100, the electron density of the 2DEG 50 may increase in the heterojunction of the AlGaN barrier/n-GaN channel. In addition, a local electron mobility may be improved in the drift region by using the undoped GaN layer 100 instead of the doped GaN or the doped AlGaN layer.

Instead of the undoped GaN layer 100, a layer formed of gallium oxide, diamond, ZnS, ZnO and the like may be used. Unless otherwise specifically specified in the present disclosure, it is assumed that the layer is formed as the undoped GaN layer.

In addition, the undoped GaN layer 100 of the enhancement-mode GaN HEMT 1100 may prevent a trap formed in the n-AlGaN barrier 80. For example, when depositing a oxide passivation layer 120 directly on the n-AlGaN barrier 80 without the undoped GaN layer 100, many traps may be generated in the n-AlGaN barrier 80. Therefore, by inserting the undoped GaN layer 100 between the n-AlGaN barrier 80 and the oxide passivation layer 120, generation of a performance problem such as a current collapse may be effectively prevented. The enhancement-mode GaN HEMT 1100 including the undoped GaN layer 100 may prevent generation of traps and solve a problem such as a current collapse.

According to the first embodiment, the undoped GaN layer 100 may comprise a first undoped GaN layer and a second undoped GaN layer arranged laterally to each other. That is, the first undoped GaN layer 100 may be disposed between a p-type gallium nitride gate (p-GaN gate) 110 and the source metal 150. The second undoped GaN layer 100 may be disposed between the p-GaN gate 110 and the drain metal 160. The first undoped GaN layer 100 may be formed in direct contact with the n-AlGaN barrier 80, the oxide passivation layer 120, the p-GaN gate 110, and the source metal 150. The second undoped GaN layer 100 may be formed in direct contact with the n-AlGaN barrier 80, the oxide passivation layer 120, the p-GaN gate 110, and the drain metal 160.

According to the first embodiment, the p-GaN gate 110 serving as a gate electrode may be formed on the n-AlGaN barrier 80. In the embodiment of the present disclosure, the p-GaN gate 110 may comprise magnesium dopants with a high doping concentration. The p-GaN gate 110 doped with the highly doped magnesium may increase an electrical potential in the channel region, and may exhaust the 2DEG 50 region completely on a boundary surface between the AlGaN barrier 80 and the n-GaN channel 40 at VGS=0. ‘Exhaust’ refers to “depleting” the charge carriers (electrons) to turn the channel off. Therefore, it helps to form the Enhancement-mode (E-mode) HEMT in a normally off-state, as the threshold voltage VT may become greater than 0V.

When a p-GaN gate 110 is placed on top of the n-AlGaN barrier 80, it acts as a “potential lifter”. The p-type material (p-GaN gate 110) has a high concentration of holes (positive charge). When this p-GaN gate 110 is in contact with the n-AlGaN barrier 80, it creates a built-in electric field that lifts the conduction band of the underlying layers. Under the p-GaN gate 110, the conduction band is pushed above the Fermi level. Since electrons can only exist in states below or near the Fermi level, they are “pushed out” or exhausted from the quantum well. At VGS=0, there are no electrons in the channel beneath the p-GaN gate 110. A positive voltage (VGS>VT) must be applied to pull the conduction band back down below the Fermi level to restore the 2DEG and let current flow.

The p-GaN gate 110 may be electrically connected to a gate metal 140. A thickness of the p-GaN gate 110 may be 80 to 100 nm. At this instance, the p-GaN gate 110 may be formed by performing an implantation process of magnesium dopants at a concentration of 1E19 to 7E19/cm3.

According to the first embodiment, an oxide passivation layer 120 may be formed on the undoped GaN layer 100 and the p-GaN gate 110. The oxide passivation layer 120 may be formed of a material such as silicon oxide or aluminum oxide. GaN surfaces are prone to dangling bonds and native oxides (Ga2O3) that degrade performance. The oxide passivation layer 120 is deposited to create a high-quality interface. It reduces the Interface State Density (Dit), which improves the subthreshold swing and ensures the threshold voltage (Vth) remains stable over time. Here, the oxide passivation layer 120 may be formed in direct contact with the p-GaN gate 110, the undoped GaN layer 100, the gate metal 140 and a nitride passivation layer 130.

The nitride passivation layer 130 may be formed on the oxide passivation layer 120. A material such as silicon nitride (SiN), silicon Oxynitride (SiON), aluminum nitride (AlN), or boron nitride (BN) are used for the nitride passivation layer 130. Unpassivated GaN surfaces have many trapped electrons (surface states) between the gate and drain. These trapped electrons act as a “Virtual Gate,” partially depleting the 2D Electron Gas (2DEG) channel and reducing the drain current during high-speed switching. The nitride passivation layer 130 may neutralize these surface traps, preventing the formation of the virtual gate and ensuring the device maintains its full current capacity at high frequencies.

According to the first embodiment, the gate metal 140 may be formed on the p-GaN gate 110. Here, the gate metal 140 may comprise a material selected from Ti/Al/Ni/Au, Ti/Al/TiN, and Ti/Al/W. The gate metal 140 may be formed by a selective etching of the oxide passivation layer 120 and the nitride passivation layer 130. Therefore, the gate metal 140 may be formed in direct contact with the p-GaN gate 110, the oxide passivation layer 120, the nitride passivation layer 130, and an inter-layer dielectric layer ILD 180.

A source metal 150 and the drain metal 160 may be formed on the n-AlGaN barrier 80. The source metal 150 and the drain metal 160 may be also disposed on the n-GaN channel 40 in which the 2DEG 50 is formed. Here, the source metal 150, and the drain metal 160 may comprise a material selected from Ti/Al/Ni/Au, Ti/Al/TiN, and Ti/Al/W. The source metal 150 and the drain metal 160 may be formed by a selective etching of the p-GaN gate 110, the oxide passivation layer 120 and the nitride passivation layer 130. Therefore, each bottom surface of the source metal 150 and the drain metal 160 is lower than a bottom surface of the gate metal 140.

According to the first embodiment, a first field plate 171 may be formed on the nitride passivation layer 130 and formed adjacent to the gate metal 140. A second field plate 172 may be formed on the nitride passivation layer 130 and the first field plate 171, and starting from an upper portion of the gate metal 140 and extending in a direction of the drain metal 160. The first and second field plates 171 and 172 may be formed adjacent to the gate metal 140 than the drain metal 160.

A third field plate 173 may be formed on the nitride passivation layer 130 and the drain metal 160. The third field plate 173 may be formed adjacent to the drain metal 160 than the gate metal 140.

The first to third field plates 171, 172 and 173 may comprise a material such as a TiN or Al in a thickness of about 100 to 500 nm. The first to third field plates (FP) 171, 172 and 173 may improve the breakdown voltage by reducing a peak of the electric field around the gate metal 140 and the drain metal 160. In addition, the first to third field plates (FP) 171, 172 and 173 may ease high electric field-related trapping effects, thereby increasing the breakdown voltage of the enhancement-mode GaN HEMT 1100. In addition, the field plates 171, 172 and 173 may reduce a trapping effect of carriers generated by a high electric field.

Thereafter, an inter-layer dielectric layer 180 formed of an inter-layer insulating material may be formed on an upper portion of the enhancement-mode GaN HEMT 1100 so as to ensure insulation. By forming a contact plug and an interconnected metal connected to the source metal 150 and the drain metal 160 in the inter-layer dielectric layer 180, the device may be connected to an additional electric circuit on an upper portion of the enhancement-mode GaN HEMT 1100.

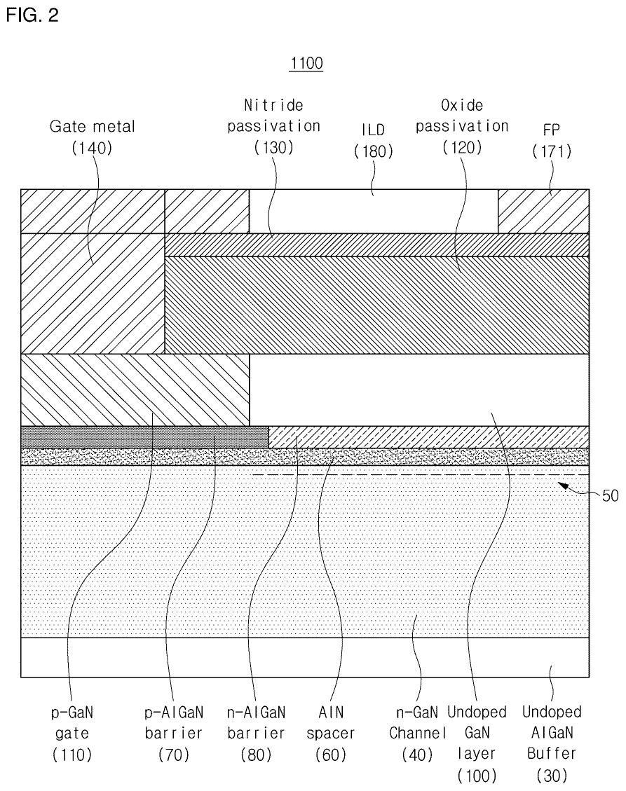

FIG. 2 is an enlarged cross-sectional view of a portion of the first GaN HEMT illustrated in FIG. 1.

As illustrated in FIG. 2, the enhancement-mode GaN HEMT 1100 may comprise the undoped AlGaN buffer 30, the n-GaN channel 40, the thin AlN spacer 60, the thick n-AlGaN barrier 80, the undoped GaN layer 100, and the p-GaN gate 110. The undoped AlGaN buffer 30 may be formed on the silicon substrate. The n-GaN channel 40 and the AlN spacer 60 may be formed on the n-GaN channel. The n-AlGaN barrier 80 may be formed on the AlN spacer 60. The undoped GaN layer 100 may be formed on the n-AlGaN barrier 80. The p-GaN gate 110 may formed on the n-GaN channel. The gate metal 140 may be formed on the p-GaN gate 110. The oxide passivation layer 120, the nitride passivation layer 130, and the first field plate 171 and the inter-layer dielectric layer 180 may be formed on the nitride passivation layer 130.

As illustrated in FIG. 2, the silicon-doped n-AlGaN barrier 80 may be formed between the AlN spacer 60 and the undoped GaN layer 100. As-deposited n-AlGaN barrier between the source metal 150 and the drain metal 160 may comprise silicon-dopants. However, the n-AlGaN barrier 80 below the p-GaN gate 110 may become a p-type AlGaN (p-AlGaN) barrier 70. The p-GaN gate 110 is doped with magnesium atoms at a high concentration equal to or more than 1E19/cm³. On the other hand, the n-AlGaN barrier 80 is doped with silicon atoms at a lower concentration.

Therefore, by annealing process conducted at high temperature such as 1300 °C, thereafter, the magnesium atoms at a high concentration of the p-GaN gate 110 may diffuse into the n-AlGaN barrier 80. The AlGaN barrier 70 below the p-GaN gate 110 may comprise both the magnesium atoms and the silicon atoms. A concentration of the diffused magnesium atoms may exceed a concentration of silicon atoms in the AlGaN barrier 70 below the p-GaN gate 110.

Therefore, the AlGaN barrier 70 below the p-GaN gate 110 may be converted from the n-AlGaN barrier 80 into the p-type AlGaN barrier (p-AlGaN barrier) 70. As a result, the p-AlGaN barrier 70 may be formed between the AlN spacer 60 and the p-GaN gate 110, and it may increase the threshold voltage Vt by increasing the potential in the channel region.

The AlN spacer 60 may have a thickness less than a thickness of the n-AlGaN barrier 80 or a thickness of the p-AlGaN barrier 70. Furthermore, the AlN spacer 60 may have a thickness less than a thickness of the undoped GaN layer 100. Here, the undoped GaN layer 100 may be formed in direct contact with the n-AlGaN barrier 80, the oxide passivation layer 120, and the p-GaN gate 110. Here, the oxide passivation layer 120 may be formed in direct contact with the undoped GaN layer 100, the nitride passivation layer 130, the gate metal 140 and the p-GaN gate 110. The gate metal 140 may be formed in direct contact with the p-GaN gate 110, the oxide passivation layer 120, the nitride passivation layer 130 and the inter-layer dielectric layer 180.

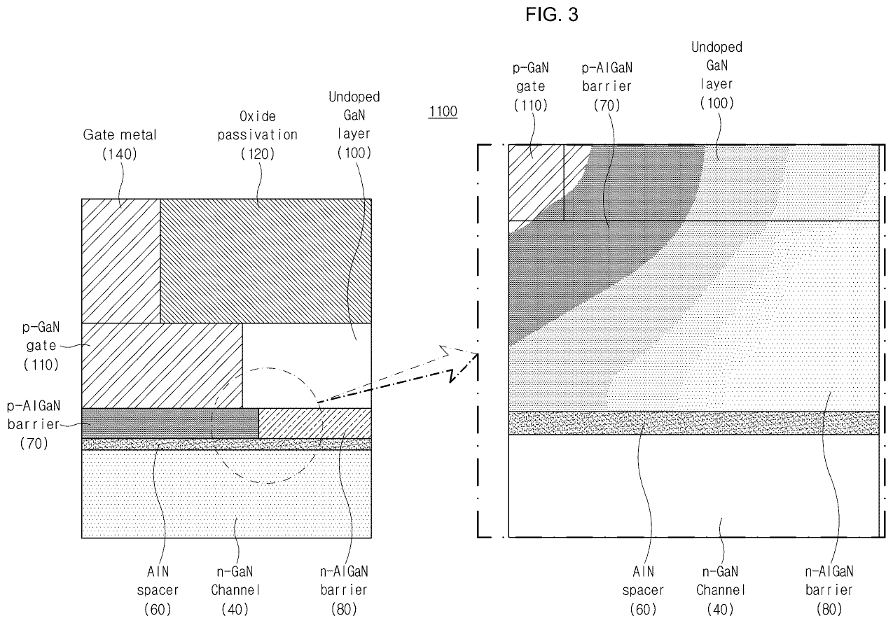

FIG. 3 is an enlarged cross-sectional view of a portion of the GaN HEMT illustrated in FIG. 2.

Referring to FIG. 3, the enhancement-mode GaN HEMT 1100 according to the embodiment of the present disclosure may comprise the n-GaN channel 40, the AlN spacer 60 formed on the n-GaN channel 40, the n-AlGaN barrier 80 formed on the AlN spacer 60, the undoped GaN layer 100 formed on the n-AlGaN barrier 80, and the p-GaN gate 110 formed on the n-GaN channel 40. The n-AlGaN barrier 80 may have a thickness greater than a thickness of the AlN spacer 60. The n-AlGaN barrier 80 may be formed between the AlN spacer 60 and the undoped GaN layer 100.

Here, the n-AlGaN barrier 80 and the p-GaN gate 110 are regions to which n-type dopants or p-type dopants are ion-injected, respectively. On the other hand, the undoped GaN layer 100 is an undoped region. Therefore, the p-type dopants may diffuse from the p-GaN gate 110 to the n-AlGaN barrier 80 and the undoped GaN layer 100. As a result, as described above, because of diffusion of the p-type dopants, the n-AlGaN barrier 80 may change into the p-AlGaN barrier 70. Therefore, the p-AlGaN barrier 70 may be formed between the AlN spacer 60 and the p-GaN gate 110.

The n-AlGaN barrier 80 may be spaced apart from the p-GaN gate 110 by the p-AlGaN barrier 70. That is, when the p-AlGaN barrier 70 is formed between the AlN spacer 60 and the p-GaN gate 110. In addition, the undoped GaN layer 100 adjacent to the p-GaN gate 110 has a high concentration of the p-type dopant due to the diffusion. However, it can be seen that as it gets away from the p-GaN gate 110, the concentration of the p-type dopant gradually decreases.

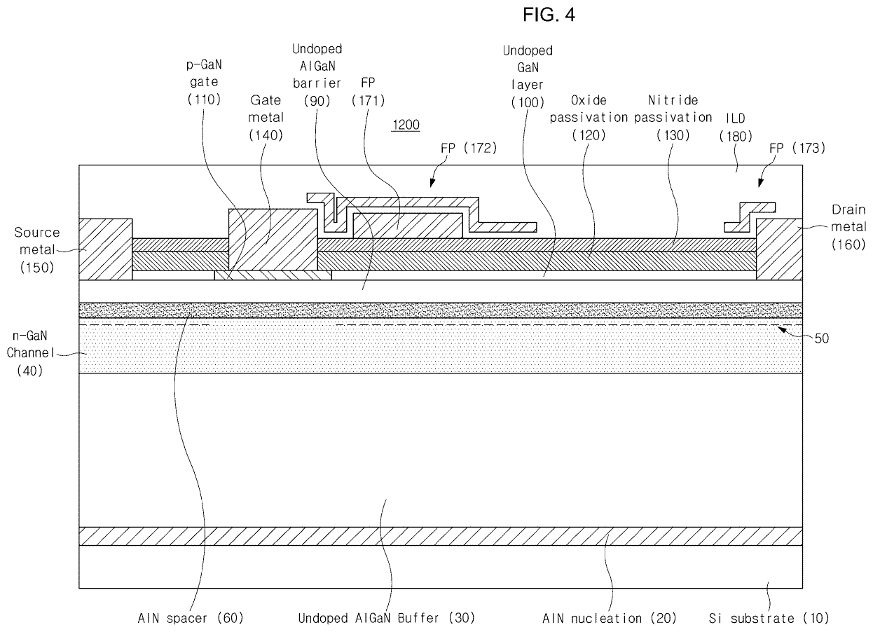

FIG. 4 is a cross-sectional view illustrating a structure of the second GaN HEMT according to a second embodiment of the present disclosure.

The second GaN HEMT in FIG. 4 is different from that of FIG. 1 because the second GaN HEMT in FIG. 4 uses the undoped AlGaN barrier 90, instead of the n-AlGaN 80.

Referring to FIG. 4, the second GaN HEMT 1200 may be formed on the silicon substrate 10. The AlN thin film layer 20 may be formed on the silicon substrate 10. The undoped AlGaN buffer 30 may be formed on the AlN thin film layer 20. The n-GaN channel 40 may be formed on the undoped AlGaN buffer 30. When the n-GaN channel 40 is formed on the undoped AlGaN buffer 30, the 2DEG 50 layer which is a very thin conductive layer may be formed on a boundary surface between the undoped AlGaN buffer 30 and the n-GaN channel 40 because of a difference between the different band gap energies of the undoped AlGaN buffer 30 (band gap: about 3.9 to 4.1 eV) and the n-GaN channel 40 (band gap: about 3.4 eV). Because of this, it is possible to move the charges with excellent performance in a high-current and high-voltage situation by the 2DEG 50.

Referring to FIG. 4, the AlN spacer 60 may be formed on the n-GaN channel 40. A function of the AlN spacer 60 is almost the same as described as above referring to FIGS. 1 and 2, and thus, part of description of the AlN spacer 60 will be omitted.

Referring to FIG. 4, the thin AlN spacer 60 is formed on the n-GaN channel 40. The AlN spacer 60 is more effective in strengthening the 2DEG 50 region. The AlN spacer 60 is a polar substance having a very great band gap of about 6.2 eV, and as the thin AlN spacer 60 is formed between the n-GaN channel 40 and the undoped AlGaN barrier 90, it is possible to form a strong electric field due to the polarity and a higher potential barrier on the boundary surface between the n-GaN channel 40 and the AlN spacer 60. Therefore, it is possible to improve a current delivery ability by forming a higher electron density in the 2DEG 50 region formed in the n-GaN channel 40. However, when applying a lower gate voltage to the HEMT in an off-state, an electron density required to turn on the HEMT may be easily reached in the 2DEG 50 region positioned below the p-GaN gate 110. Therefore, when adding the structure of the AlN spacer 60, the drain current of the enhancement-mode GaN HEMT 1100 can be easily increased and therefore, the threshold voltage can be lowered.

The p-AlGaN barrier 70 may be formed between the AlN spacer 60 and the p-GaN gate 110. The thick p-AlGaN barrier 70 may be formed with a thickness of 15 to 25nm. The p-AlGaN barrier 70 may comprise magnesium-dopants. The p-AlGaN barrier 70 below the p-GaN gate 110 may increase the threshold voltage Vt by increasing the potential in the channel region. The undoped AlGaN barrier 90 may be formed on the AlN spacer 60. Therefore, the undoped AlGaN barrier 90 is formed between the AlN spacer 60 and the undoped GaN layer 100. The undoped AlGaN barrier 90 may increase the stability of the enhancement-mode GaN HEMT 1100 by strengthening the 2DEG 50 region and confining the charge so that the charge cannot escape from the n-GaN channel 40.

According to the second embodiment, the p-GaN gate 110 doped with p-type dopants may be formed on the p-AlGaN barrier 70. The p-GaN gate 110 may comprise highly doped magnesium dopants. The p-GaN gate 110 may increase a potential in the channel region, and may exhaust the 2DEG 50 region completely on a boundary surface between the p-AlGaN barrier 70 and the n-GaN channel 40 at VGS=0. Therefore, it helps to form the E-mode HEMT in a normally off-state, as the threshold voltage VT may become greater than 0V.

According to the second embodiment, an oxide passivation layer 120 and a nitride passivation layer 130 may be formed on the undoped GaN layer 100. According to the present embodiment, the oxide passivation layer 120 and the nitride passivation layer 130 have been described above, and description thereof will be omitted.

According to the second embodiment, by a selective etching of the oxide passivation layer 120 and the nitride passivation layer 130, the gate metal 140, the source metal 150 and the drain metal 160 may be formed simultaneously. The gate metal 140, the source metal 150, and the drain metal 160 may be formed of the same material. For example, the gate metal 140, the source metal 150, and the drain metal 160 may be formed as a material-stacked layer among Ti/Al/Ni/Au, Ti/Al/TiN, and Ti/Al/W.

According to the second embodiment, the field plates 171, 172 and 173 may be formed around the gate metal 140 and the drain metal 160 where the electric field is concentrated. The field plates 171, 172 and 173 may ease the electric field of the gate metal 140 and the drain metal 160, thereby increasing the breakdown voltage of the enhancement-mode GaN HEMT 1100. In addition, the field plates 171, 172 and 173 may reduce a trapping effect of carriers generated by a high electric field. Thereafter, an inter-layer dielectric layer 180 formed of an inter-layer insulating material may be formed on an upper portion of the enhancement-mode GaN HEMT 1100 so as to ensure insulation. By forming a metal region connected to the source metal 150 and the drain metal 160 in the inter-layer dielectric layer 180, the device may be connected to an additional electric circuit on an upper portion of the enhancement-mode GaN HEMT 1100.

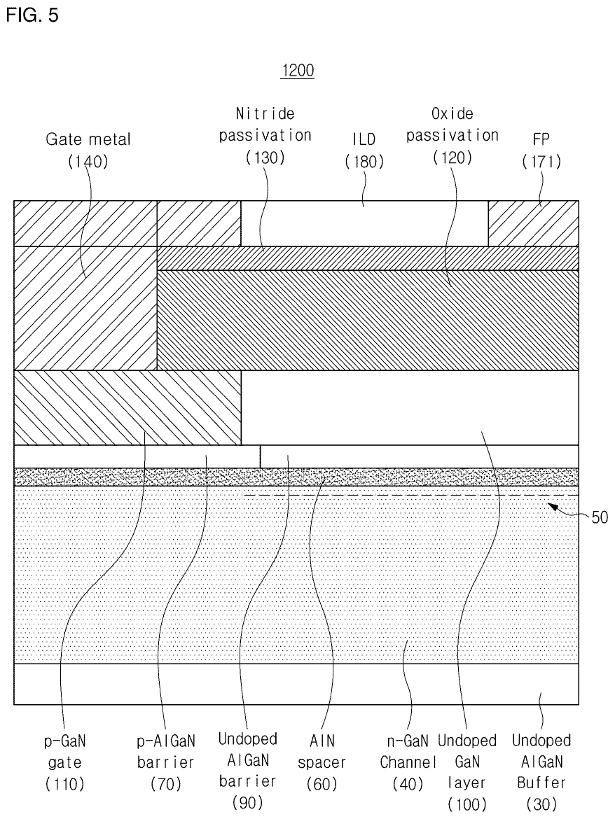

FIG. 5 is an enlarged cross-sectional view of a portion of the second GaN HEMT illustrated in FIG. 4.

Referring to FIG. 5, the second GaN HEMT 1200 may comprise a structure of the thin AlN spacer 60, the p-AlGaN barrier 70, the undoped AlGaN barrier 90, and the undoped GaN layer 100. It is a structure in which the undoped AlGaN barrier 90 is formed on the AlN spacer 60. In addition, the AlGaN barrier below the p-GaN gate 110 may be maintained as the p-AlGaN barrier 70. The p-AlGaN barrier 70 is the p-AlGaN barrier doped with magnesium, and may increase a potential in the channel region, and increase the threshold voltage Vt sequentially. Therefore, while having the threshold voltage of the second GaN HEMT 1200 to be similar to the threshold voltage of the first enhancement-mode GaN HEMT 1100, it is possible to further improve the performance of the enhancement-mode GaN HEMT 1100 by the undoped AlGaN barrier 90 formed in the drift region of the second GaN HEMT 1200.

According to the second embodiment, the p-AlGaN barrier 70 may comprise magnesium Mg of a p-type by as much as 5E16 to 1E18/cm3. When increasing a concentration of the magnesium of the p-AlGaN barrier 70, the threshold voltage may increase, whereas a drain saturation current gets lowered. The thin AlN spacer 60 and the thick p-AlGaN barrier 70 (band gap is about 3.9 to 4.1 eV) may increase stability of the HEMT 1200 by strengthening the 2DEG 50 region and allowing a charge not to escape from the n-GaN channel 40. Here, the p-AlGaN barrier 70 may be formed in direct contact with the AlN spacer 60, the undoped GaN layer 100, and the p-GaN gate 110.

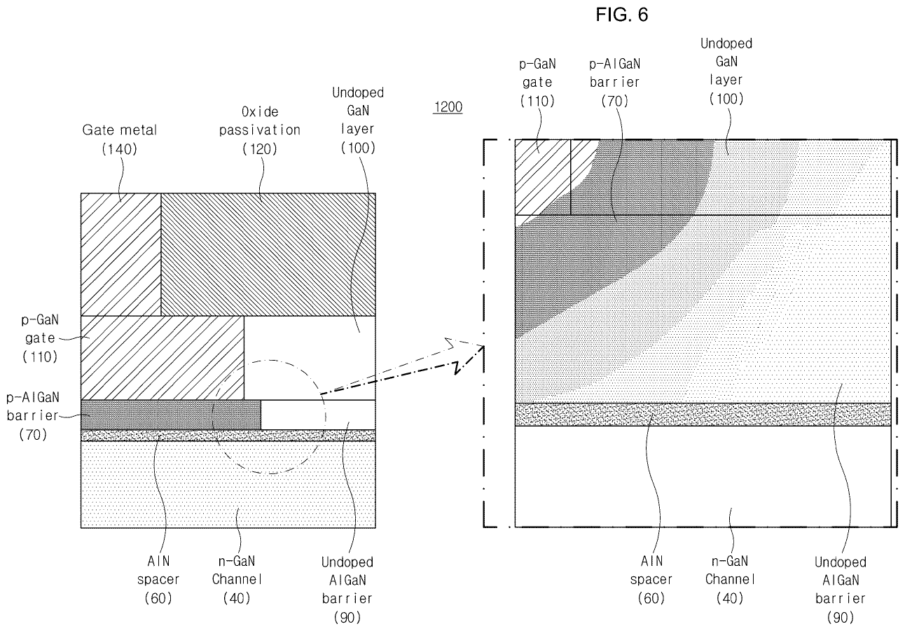

FIG. 6 is an enlarged cross-sectional view of a portion of the second GaN HEMT illustrated in FIG. 5.

Referring to FIG. 6, in some region of the second GaN HEMT 1200, a structure of the thin AlN spacer 60, the p-AlGaN barrier 70, the undoped AlGaN barrier 90, the undoped GaN layer 100, and the p-GaN gate 110 is illustrated in more detail. The second GaN HEMT 1200 may comprise the n-GaN channel 40, the AlN spacer 60 formed on the n-GaN channel 40, the p-AlGaN barrier 70 and the undoped AlGaN barrier 90 formed on the AlN spacer 60, the undoped GaN layer 100 formed on the undoped AlGaN barrier 90, and the p-GaN gate 110 formed on the p-AlGaN barrier 70.

The p-AlGaN barrier 70 and the undoped AlGaN barrier 90 are formed in parallel to each other, and share a bottom surface with each other. The p-AlGaN barrier 70 and the undoped AlGaN barrier 90 are in direct contact with the AlN spacer 60, and each of the p-AlGaN barrier 70 and the undoped AlGaN barrier 90 may have a thickness greater than a thickness of the AlN spacer 60. The p-AlGaN barrier 70 and the undoped AlGaN barrier 90 are in direct contact with the p-GaN gate 110 and the undoped AlGaN barrier 90, respectively.

The undoped AlGaN barrier 90 is in contact with the p-AlGaN barrier 70 and the p-GaN gate 110 on a side surface, in contact with the AlN spacer 60 on a bottom surface, and in contact with the undoped GaN layer 100 on an upper surface.

Here, the p-AlGaN barrier 70 and the p-GaN gate 110 may be a region to which a p-type dopant is ion-injected. On the other hand, the undoped AlGaN layer 90 is a region on which an n-type or a p-type dopant is not doped. Therefore, the p-type dopant may diffuse from the p-AlGaN barrier 70 and the p-GaN gate 110 to the undoped AlGaN barrier 90 which is in contact with the p-AlGaN barrier 70 and the p-GaN gate 110. Thus, as illustrated in FIG. 6, the undoped AlGaN barrier 90 in close contact with the p-AlGaN barrier 70 and the p-GaN gate 110 has a high concentration of the p-type dopant because of the diffusion. However, it is seen that as it gets away from the p-GaN gate 110, the concentration of the p-type dopant of the undoped AlGaN barrier 90 gradually decreases.

Like the undoped AlGaN layer 90, the undoped GaN layer 100 is a region on which an n-type or a p-type dopant is not doped. Therefore, the p-type dopant may diffuse to the undoped GaN layer 100 which is in contact with the p-GaN gate 110. Thus, as illustrated in FIG. 6, the undoped GaN layer 100 in close contact with the p-GaN gate 110 has a high concentration of the p-type dopant because of the diffusion. However, it is seen that as it gets away from the p-GaN gate 110, the concentration of the p-type dopant gradually decreases.

Although the present disclosure has been described with reference to the embodiment shown in the drawings, this is just an example and it will be understood by those skilled in the art that various modifications and equivalent thereto may be made. Therefore, the true technical scope of the present disclosure should be determined by the spirit of the appended claims.

What is claimed is:

1. A gallium nitride high electron mobility transistor (GaN HEMT), comprising:
a silicon substrate;
an undoped aluminum gallium nitride buffer (undoped AlGaN buffer) formed on the silicon substrate;
an n-type GaN channel (n-GaN channel) formed on the undoped AlGaN buffer;
a two-dimensional electron gas (2DEG) at a heterointerface between the n-GaN channel and an aluminum nitride spacer (AlN spacer);
the AlN spacer formed on the n-GaN channel;
an n-type AlGaN barrier (n-AlGaN barrier) formed on the AlN spacer;
an undoped GaN layer formed on the n-AlGaN barrier;
a p-type gallium nitride gate (p-GaN gate) formed over the n-AlGaN barrier and laterally adjacent to the undoped GaN layer;
a gate metal formed on the p-GaN gate; and
a source metal and a drain metal formed on the n-GaN channel, the source metal and the drain metal providing ohmic contact to the n-GaN channel,
wherein the n-AlGaN barrier is formed between the AlN spacer and the undoped GaN layer, and the transistor is an enhancement-mode device configured to be normally off at VGS=0 V.

2. The GaN HEMT of claim 1,
wherein the n-AlGaN barrier has a thickness greater than a thickness of the AlN spacer, and the AlN spacer has a thickness from 0.5 nm to 1.0 nm.

3. The GaN HEMT of claim 1,
wherein the undoped GaN layer comprises:
a first undoped GaN layer disposed between the p-GaN gate and the source metal; and
a second undoped GaN layer disposed between the p-GaN gate and the drain metal.

4. The GaN HEMT of claim 1, further comprising:
an oxide passivation layer formed on the undoped GaN layer;
a nitride passivation layer formed on the oxide passivation layer; and
an inter-layer dielectric layer formed on the nitride passivation layer,
wherein the oxide passivation layer is in direct contact with the p-GaN gate, the undoped GaN layer, and the gate metal, the oxide passivation layer comprising SiO₂ or Al₂O₃ and the nitride passivation layer comprising SiN, SiON, AlN, or BN, and
wherein the oxide passivation layer and the nitride passivation layer are configured to reduce interface state density and mitigate current collapse.

5. The GaN HEMT of claim 1, further comprising:
a first field plate formed on the nitride passivation layer and laterally adjacent to the gate metal;
a second field plate formed over the first field plate, overlapping a portion of the gate metal and extending toward the drain metal; and
a third field plate overlapping formed to overlap a portion of the drain metal,
wherein the field plates are configured to reduce peak electric field and enhance breakdown voltage.

6. The GaN HEMT of claim 4,
wherein the undoped GaN layer is formed in direct contact with the n-AlGaN barrier, the p-GaN gate, and the oxide passivation layer,
wherein the p-GaN gate is formed in direct contact with the undoped GaN layer, the gate metal, and the oxide passivation layer, and
wherein the gate metal is formed in direct contact with the p-GaN gate, the oxide passivation layer, the nitride passivation layer, and the inter-layer dielectric layer.

7. A gallium nitride high electron mobility transistor (GaN HEMT), comprising:
a silicon substrate, an undoped AlGaN buffer and an n-GaN channel formed sequentially;
an AlN spacer formed on the n-GaN channel;
a p-AlGaN barrier and an undoped AlGaN barrier formed on the AlN spacer;
a p-GaN gate and an undoped GaN layer formed on the p-AlGaN barrier and the undoped AlGaN barrier, respectively;
a gate metal formed on the p-GaN gate; and
a source metal and a drain metal formed of a same metal stack as the gate metal, spaced apart from the gate metal, and formed in direct contact with the n-GaN channel,
wherein the transistor is an enhancement-mode device configured to be normally off at VGS=0 V.

8. The GaN HEMT of claim 7,
wherein the p-AlGaN barrier and the undoped AlGaN barrier are formed in parallel to each other and share a bottom surface with each other.

9. The GaN HEMT of claim 7,
wherein the undoped AlGaN barrier contacts the p-AlGaN barrier on a side surface, contacts the AlN spacer on a bottom surface, and contacts the undoped GaN layer on an upper surface.

10. The GaN HEMT of claim 7, further comprising:
an oxide passivation layer formed on the undoped GaN layer;
a nitride passivation layer formed on the oxide passivation layer; and
an inter-layer dielectric layer formed on the nitride passivation layer,
wherein the oxide passivation layer is in direct contact with the p-GaN gate, the undoped GaN layer, and the gate metal, and
wherein the oxide passivation layer and the nitride passivation layer are configured to neutralize surface states between the gate metal and the drain metal and suppress a virtual-gate effect during high-speed switching.

11. The GaN HEMT of claim 10,
wherein the undoped GaN layer is in direct contact with the p-GaN gate and the oxide passivation layer,
wherein the p-GaN gate is in direct contact with the undoped GaN layer, the oxide passivation layer, the p-AlGaN barrier, and the gate metal, and
wherein the gate metal is in direct contact with the p-GaN gate, the oxide passivation layer, the nitride passivation layer, and the inter-layer dielectric layer.

12. A method of manufacturing an enhancement-mode gallium nitride high electron mobility transistor (GaN HEMT), the method comprising:
forming an AlN thin film layer on a silicon substrate;
forming an undoped AlGaN buffer on the AlN thin film layer;
forming an n-GaN channel on the undoped AlGaN buffer;
forming an AlN spacer on the n-GaN channel;
forming an AlGaN barrier on the AlN spacer;
forming a p-GaN gate on the AlGaN barrier;
annealing the semiconductor structure formed by the AlGaN barrier and the p-GaN gate to diffuse magnesium from the p-GaN gate into the AlGaN barrier to convert, beneath the p-GaN gate, a portion of the AlGaN barrier to a p-AlGaN barrier;
forming an undoped GaN layer on the AlGaN barrier laterally adjacent the p-GaN gate;
forming an oxide passivation layer on the undoped GaN layer and a nitride passivation layer on the oxide passivation layer; and
forming source, drain, and gate metals, the source and drain metals contacting the n-GaN channel,
wherein the device is normally off at VGS=0 V, and
wherein the undoped GaN layer and a passivation stack formed by the oxide passivation layer and the nitride passivation layer are configured to reduce trap formation and mitigate current collapse.

13. The method of claim 12,
wherein the AlN spacer has a thickness from 0.5 nm to 1.0 nm and the AlGaN barrier has a thickness greater than the thickness of the AlN spacer.

14. The method of claim 12,
wherein the undoped GaN layer comprises first and second undoped GaN regions disposed on opposite sides of the p-GaN gate, respectively adjacent the source metal and the drain metal.

15. The method of claim 12,
wherein the oxide passivation layer comprises silicon oxide or aluminum oxide and the nitride passivation layer comprises silicon nitride, silicon oxynitride, aluminum nitride, or boron nitride, to reduce interface state density and suppress a virtual-gate effect between the gate metal and the drain metal.

16. The method of claim 12, further comprising:
forming at least one field plate over the nitride passivation layer to reduce peak electric fields near the gate metal or the drain metal,
wherein the gate metal, the source metal, and the drain metal comprise a common metal stack selected from Ti/Al/Ni/Au, Ti/Al/TiN, and Ti/Al/W.
